(19) United States
(12) Patent Application Publication
(10) Pub. No.: US 2026/0314287 A1
(43) Pub. Date: Oct. 8, 2026

(54) BASE FILM AGENT AND PROCESSING METHOD FOR WORKPIECE

(71) Applicant: DISCO CORPORATION, Tokyo (JP)

(72) Inventors: Yu ZHAO, Tokyo (JP); Yuki NISHIJIMA, Tokyo (JP); Shin TABATA, Tokyo (JP); Sho OSAWA, Tokyo (JP); Ryuji UCHIDA, Tokyo (JP)

(21) Appl. No.: 19/637,250

(22) Filed: Apr. 2, 2026

(30) Foreign Application Priority Data
Apr. 7, 2025 (JP) 2025-063180

(51) Int. Cl. H10P 50/00; B23K 26/364; B23K 101/40; H10P 14/68; H10P 50/24; H10P 58/00; H10P 70/00

(52) U.S. Cl. CPC H10P 50/692; B23K 26/364; H10P 14/683; H10P 50/242; H10P 50/695; H10P 58/00; H10P 70/30; B23K 2101/40

(57) ABSTRACT

A base film agent may be for a protective film coated on a workpiece when the workpiece is processed, the base film agent contains water-soluble compounds, and a solvent that dissolves the water-soluble compounds, and 50 wt % or more of the water-soluble compounds has a molecular weight of 2000 or less.

### CROSS-REFERENCE TO RELATED APPLICATIONS

This application is based on and claims priority under 35 USC 119 from Japanese Patent Application No. 2025-063180 filed on Apr. 7, 2025, the contents of which are incorporated herein by reference.

### TECHNICAL FIELD

The present disclosure relates to a base film agent and a processing method for a workpiece.

### BACKGROUND ART

In recent years, with high integration of devices, hybrid bonding has begun to be adopted, in which electrodes on surfaces of the devices are connected. In the hybrid bonding, since the surfaces of the devices are bonded to each other, it is necessary to reduce foreign matter adhering to the surfaces of the devices in order to prevent bonding failure.

As a technique for reducing adhesion of foreign matter to a surface of a device when the device is divided from a wafer, for example, a technique for dividing a device from a wafer by plasma etching has been studied (for example, Patent Literature 1). In Patent Literature 1, a surface of a wafer on which a device is formed is coated with a water-soluble resin (protective film), and the wafer is irradiated with a laser beam to remove a functional layer along streets together with the protective film, thereby providing a mask at the time of plasma etching.
Patent Literature 1: JP2018-098318A

### SUMMARY

In Patent Literature 1, a cleaning step of removing a protective film coated on a wafer with cleaning water is performed after plasma etching. In this cleaning step, there is room for improvement to improve the cleaning effect and prevent the protective film from remaining as foreign matter on the surface of the device.

The present disclosure provides a base film agent (underlayer film composition) and a processing method for a workpiece capable of preventing the protective film from remaining on the workpiece after cleaning.

A base film agent of one aspect of the present disclosure is
a base film agent, which may be for a protective film coated on a workpiece when the workpiece is processed,
the base film agent includes:
water-soluble compounds; and
a solvent that dissolves the water-soluble compounds, and
50 wt % or more of the water-soluble compounds has a molecular weight of 2000 or less.

A processing method for a workpiece according to one aspect of the present disclosure includes:
forming a base film by coating a surface of the workpiece with the base film agent;
forming the protective film by coating a surface of the base film with a protective film agent;
removing portions of the protective film and the base film overlapping planned processing lines set on the workpiece by irradiating the workpiece with a laser beam having a wavelength absorbed by the protective film and the base film along the planned processing lines, thereby forming a mask;
removing portions of the workpiece exposed from the mask by applying plasma to the portions exposed from the mask; and
removing the protective film and the base film from the workpiece by applying plasma to the workpiece and then ejecting a fluid.

A device chip manufacturing method according to one aspect of the present disclosure is a device chip manufacturing method in which a workpiece is divided along a plurality of planned processing lines to form a plurality of device chips, and the device chip manufacturing method includes:
forming a base film by coating a surface of the workpiece with the base film agent;
forming the protective film by coating a surface of the base film with a protective film agent;
removing portions of the protective film and the base film overlapping the planned processing lines set on the workpiece by irradiating the workpiece with a laser beam having a wavelength absorbed by the protective film and the base film along the planned processing lines, thereby forming a mask;
removing portions of the workpiece exposed from the mask by applying plasma to the portions exposed from the mask, thereby dividing the workpiece along the planned processing lines; and
removing the protective film and the base film from the workpiece by applying plasma to the workpiece and then ejecting a fluid.

A processing method for a workpiece according to one aspect of the present disclosure includes:
forming a base film by coating a surface of the workpiece with the base film agent;
forming the protective film by coating a surface of the base film with a protective film agent;
removing portions of the protective film, the base film, and the workpiece that overlap a planned processing line set on the workpiece by irradiating the workpiece with a laser beam having a wavelength absorbed by the protective film, the base film, and the workpiece along the planned processing line; and
removing the protective film and the base film from the workpiece by ejecting a fluid after irradiating the workpiece with the laser beam.

A device chip manufacturing method according to another aspect of the present disclosure is a device chip manufacturing method in which a workpiece is divided along a plurality of planned processing lines to form a plurality of device chips, and the device chip manufacturing method includes:
forming a base film by coating a surface of the workpiece with the base film agent;
forming the protective film by coating a surface of the base film with a protective film agent;
removing portions of the protective film, the base film, and the workpiece overlapping the planned processing lines set on the workpiece by irradiating the workpiece with a laser beam having a wavelength absorbed by the protective film, the base film, and the workpiece along the planned processing lines, thereby dividing the workpiece along the planned processing lines; and
removing the protective film and the base film from the workpiece by spraying a fluid after irradiating the workpiece with the laser beam.

### BRIEF DESCRIPTION OF DRAWINGS

FIG. 1 is a perspective view showing an example of a workpiece coated with a base film agent and a protective film agent.

FIG. 2 is an example of a flowchart of a processing method for a workpiece according to a first embodiment.

FIG. 3 is a cross-sectional view showing how a workpiece is coated with a base film agent.

FIG. 4 is a cross-sectional view showing a state in which a base film of the workpiece is coated with a protective film agent.

FIG. 5 is a cross-sectional view showing how the base film and the protective film are formed on the workpiece.

FIG. 6 is a cross-sectional view showing how the protective film and the base film are irradiated with a laser beam.

FIG. 7 is a cross-sectional view showing a state in which a mask is formed on the workpiece.

FIG. 8 is a cross-sectional view showing an example of a plasma etching apparatus.

FIG. 9 is a cross-sectional view showing how the workpiece is processed by plasma.

FIG. 10 is a cross-sectional view showing a workpiece divided along a planned processing line.

FIG. 11 is a cross-sectional view showing how the protective film and the base film are removed by a cleaning device.

FIG. 12 is an example of a flowchart of a processing method for a workpiece according to a second embodiment.

FIG. 13 is a cross-sectional view showing a state in which the workpiece is processed by laser ablation.

### DESCRIPTION OF EMBODIMENTS

Hereinafter, embodiments of a base film agent for a protective film and a processing method for a workpiece of the present disclosure will be described with reference to the accompanying drawings.

First, the workpiece will be described.

### [Workpiece]

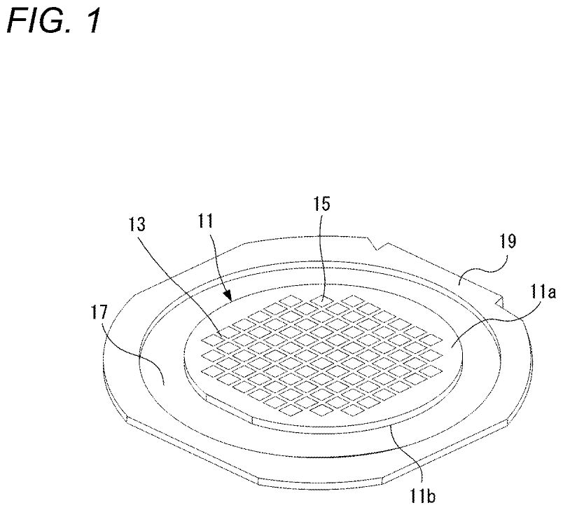

FIG. 1 is a perspective view of a workpiece 11 according to the present embodiment. The workpiece 11 is a wafer having a disk shape and is made of, for example, a semiconductor material. The semiconductor material is, for example, silicon (Si) or silicon carbide (SiC), but the material is not particularly limited.

The workpiece 11 has a front surface 11a and a back surface 11b opposite to the front surface 11a. A plurality of devices 15 are formed on the front surface 11a. Each of the devices 15 is, for example, an integrated circuit (IC) or a large scale integration (LSI). The workpiece 11 is partitioned into a plurality of small regions by a plurality of planned processing lines 13 (streets) intersecting each other, and the devices 15 are formed in small regions. The workpiece 11 may have an insulating film such as a silicon oxide film (SiO₂ film), a silicon nitride film (SiN film), or a nitrogen-doped silicon carbide film (SiCN film).

A tape 17 (dicing tape) having a size capable of covering the entire back surface 11b is attached to the back surface 11b of the workpiece 11. An annular frame 19 surrounding the workpiece 11 is fixed to a peripheral edge of the tape 17. In the present embodiment, the workpiece 11 and the frame 19 are integrated via the tape 17, but the tape 17 and the frame 19 may not necessarily be used when the workpiece 11 is coated with a base film agent and a protective film agent.

### [Protective Film Agent]

Next, a protective film agent coated on the workpiece 11 will be described. The protective film agent is coated on the workpiece 11 when plasma etching or laser ablation to be described later is performed. The protective film agent typically contains a water-soluble resin, a light absorbing material, and a solvent that dissolves the resin and the light absorbing material.

The water-soluble resin is, for example, a polymer compound in which 0.5 g or more of the resin can be dissolved in 100 g of water at 25° C. Examples of the water-soluble resin include polyvinyl pyrrolidone, polyvinyl alcohol, hydroxypropyl cellulose, hydroxypropyl methyl cellulose, polyethylene glycol, polyethylene oxide, methyl cellulose, ethyl cellulose, polyacrylic acid, poly-N-vinylacetamide, polyglycerin, polyoxazoline (e.g., poly(2-methyl-2-oxazoline), poly(2-ethyl-2-oxazoline), poly(2-propyl-2-oxazoline), polyparahydroxystyrene, polystyrene sulfonic acid, styrene maleic acid, and (meth)acrylic resin.

As the water-soluble resin, any of these polymer compounds may be used alone, or a plurality of these polymer compounds may be used in any combination. That is, as the protective film agent, one kind of water-soluble resin may be used alone, or two or more kinds of water-soluble resins may be used in combination. Further, as the water-soluble resin, a copolymer of these polymer compounds (polyvinyl alcohol/acrylic acid/methyl methacrylate copolymer, vinyl acetate/vinylpyrrolidone copolymer, ethylene/vinyl alcohol copolymer, polyvinyl alcohol/polyethylene glycol copolymer, or the like) may be used. However, in the protective film agent, other polymer compounds may be used as a water-soluble resin.

The light absorbing material is a material that absorbs light having a wavelength in at least an ultraviolet region (preferably 250 nm or more and 400 nm or less). Examples of the light absorbing material include cinnamic acid compounds, benzophenone compounds, anthraquinone compounds, and flavonol compounds. These light absorbing material are preferably water-soluble. A water-soluble compound refers to, for example, a compound capable of dissolving 0.5 g or more in 100 g of water at 25° C.

The solvent is, for example, water. However, in the protective film agent, another solvent represented by an organic solvent miscible with water may be used together with water. Examples of such an organic solvent include propylene glycol monomethyl ether (PGME), methanol, ethanol, isopropanol, acetone, and tetrahydrofuran. In the protective film agent, one kind of organic solvent may be used alone, or two or more kinds of organic solvents may be used in combination.

An antioxidant may be added to the protective film agent for the purpose of preventing deterioration over time. Typical examples of the antioxidant include L-ascorbic acid (that is, vitamin C), D-araboascorbic acid, ethyl ascorbic acid, and ascorbic acid 2-glucoside. Any of these antioxidants may be added to the protective film agent alone, or a plurality of these antioxidants may be added in any combination.

In addition, a preservative may be added to the protective film agent for the purpose of preventing corrosion thereof. Typical examples of the preservative include methyl 4-hydroxybenzoate.

For the purpose of improving the handleability of the protective film agent, a thickener may be added within a range that does not impair the efficacy of the present disclosure. Examples of the thickener include guar gum, xanthan gum, polyacrylic acid, and polymethacrylic acid.

In addition, for the purpose of reducing the hardness of the protective film, a plasticizer may be added to the protective film agent. The plasticizer has a function of entering between molecular chains of the water-soluble resin and reducing a bonding force between the molecular chains. When the protective film contains the plasticizer, the flexibility of the protective film is improved, that is, the hardness of the protective film can be reduced as compared with a case where the protective film does not contain the plasticizer. Typical examples of the plasticizer include glycerin, diglycerin, sorbitol, ethylene glycol, diethylene glycol, triethylene glycol, tetraethylene glycol, polyethylene glycol, propylene glycol, dipropylene glycol, neopentyl glycol, trimethylolpropane (TMP), polyether polyol, 2-methyl-1,3-propanediol, and ethanolamine.

The contents of the water-soluble resin, the light absorbing material, and the solvent in the protective film agent are freely set within a range in which the performance of the intended protective film agent is appropriately realized. When the content of the water-soluble resin in the protective film agent is increased, a thickness of the protective film formed of the protective film agent is easily increased. In addition, a water-soluble resin having the same structure is generally easily dissolved in a solvent as the molecular weight of the water-soluble resin decreases, and when the same concentration is realized, the water-soluble resin is easily fed with a low viscosity.

From the viewpoint of the thickness of the protective film and the ease of liquid feeding, a weight average molecular weight of the water-soluble resin is preferably 250000 or less, and more preferably 100000 or less. The light absorbing material can be contained in any content with the solubility thereof as an upper limit within a range in which the performance of the intended protective film agent is not impaired.

Typically, the content of the water-soluble resin is 5 parts by mass to 35 parts by mass and the content of the light absorbing material is 1 part by mass to 25 parts by mass with respect to 100 parts by mass of the entire protective film agent.

In addition, the protective film agent as described above is preferably further passed through an ion exchange resin. Thus, impurities such as metal ions can be removed from the protective film agent. With this ion exchange, a pH of the protective film agent is 4 or less. From the viewpoint of preservatives, the pH is preferably 4 or less, or the pH of the protective film agent may be adjusted to 4 or more by adding a base such as triethanolamine.

### [Base Film Agent]

Next, the base film agent coated on the workpiece 11 will be described. The base film agent is coated on the front surface 11a of the workpiece 11 before being coated with the protective film agent described above, and forms a base of the protective film. The base film agent typically contains water-soluble compounds and a solvent that dissolves the water-soluble compounds.

In the present disclosure, 50 wt % or more of the water-soluble compounds contained in the base film agent has a molecular weight of 2000 or less. The water-soluble compounds may contain a component having a molecular weight of 2000 or more, but the component having a molecular weight of 2000 or more is less than 50 wt %.

The component having a molecular weight of 2000 or less in the water-soluble compounds contained in the base film agent is preferably a compound containing one or more hydroxyl groups (that is, alcohol).

The component having a molecular weight of 2000 or less in the water-soluble compounds contained in the base film agent is preferably a compound that is solid at 20° C. (at room temperature). In other words, the component having a molecular weight of 2000 or less in the water-soluble compounds contained in the base film agent is preferably a compound having a melting point of 20° C. or more.

For example, 50 wt % or more of the water-soluble compounds contained in the base film agent is trimethylolpropane (TMP) and is represented by the following chemical formula.

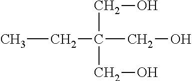

Trimethylolpropane is a low-molecular alcohol having a molecular weight of about 134. Trimethylolpropane has a melting point of about 58° C. and is solid at 20° C.

### [Processing Method for Workpiece]

Next, an embodiment according to a processing method for the workpiece 11 will be described. First, a processing method for the workpiece 11 by plasma etching will be described as a first embodiment of the processing method, and next, a processing method for the workpiece 11 by laser ablation will be described as a second embodiment of the processing method.

### First Embodiment

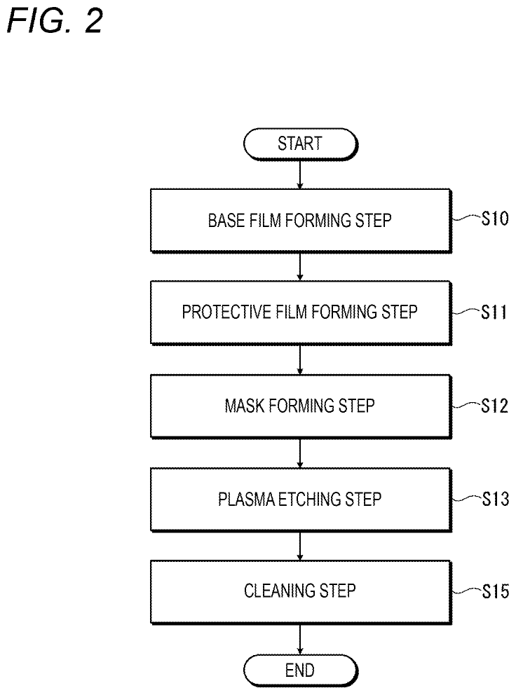

FIG. 2 is a flowchart showing the processing method for the workpiece 11 according to the first embodiment. The processing method for the workpiece 11 according to the first embodiment includes a base film forming step S10, a protective film forming step S11, a mask forming step S12, a plasma etching step S13, and a cleaning step S14. The plasma etching is a process of exposing the workpiece 11 to highly reactive plasma, and the above-described protective film agent is used to form a mask during the plasma etching.

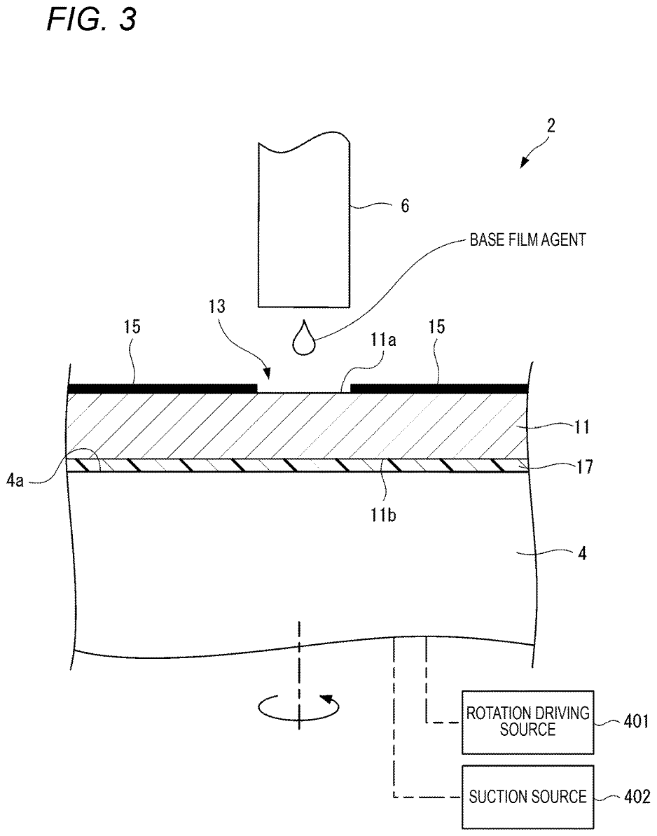

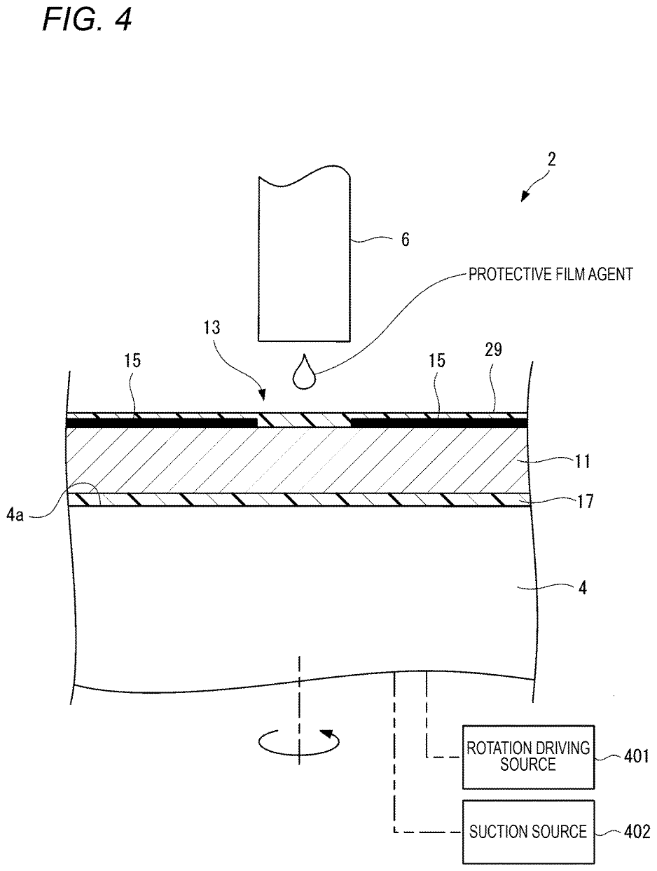

As shown in FIGS. 3 and 4, in the base film forming step S10, the base film 29 is formed by coating the front surface 11a of the workpiece 11 with a base film agent. FIG. 3 is a cross-sectional view showing a state in which the workpiece 11 is coated with a base film agent. FIG. 4 is a cross-sectional view showing a state in which the base film 29 is formed on the workpiece 11. In FIGS. 3 and 4, for convenience of description, side surfaces of only some elements are shown.

A spin coater 2 is used when the workpiece 11 is coated with a base film agent. The spin coater 2 includes a spinner table (holding table) 4 for holding a workpiece 11, and a nozzle 6 for dropping a base film agent.

The spinner table 4 is coupled to a rotation driving source 401 including a motor and the like, and rotates around a rotation axis substantially parallel to a vertical direction. A part of an upper surface of the spinner table 4 serves as a holding surface 4a for holding the workpiece 11. The holding surface 4a is connected to a suction source 402 such as a vacuum pump via a flow path formed inside the spinner table 4. A plurality of clamps (not shown) for fixing the annular frame 19 are provided around the spinner table 4.

The nozzle 6 is disposed above the spinner table 4 and drops a liquid base film agent. Specifically, the nozzle 6 is disposed on the rotation axis of the spinner table 4 above the spinner table 4.

To describe the base film forming step S10 in detail, first, in the base film forming step S10, the tape 17 attached to the back surface 11b of the workpiece 11 is brought into contact with the holding surface 4a of the spinner table 4 to apply a negative pressure of the suction source 402, and the frame 19 is fixed by clamps.

Subsequently, in the base film forming step S10, the base film agent is dropped from the nozzle 6, and the spinner table 4 is rotated to apply the base film agent to the workpiece 11.

Subsequently, in the base film forming step S10, the base film agent is dried. Thus, the base film 29 is completed on the workpiece 11. Examples of a drying method include baking, application of xenon pulses, application of infrared radiation, in addition to natural drying. By using a method such as baking, application of xenon pulses, application of infrared radiation, the base film agent can be quickly dried to form the base film 29.

In the present embodiment, the workpiece 11 is coated with the base film agent by spin coating using the spin coater 2, or the workpiece 11 may be coated with the base film agent by another method such as spray coating. Examples of the spray coating include spraying with two fluids, spraying by ultrasonic atomization, and electrostatic spraying. By using spin coating, a uniform base film 29 can be easily formed on the entire workpiece 11.

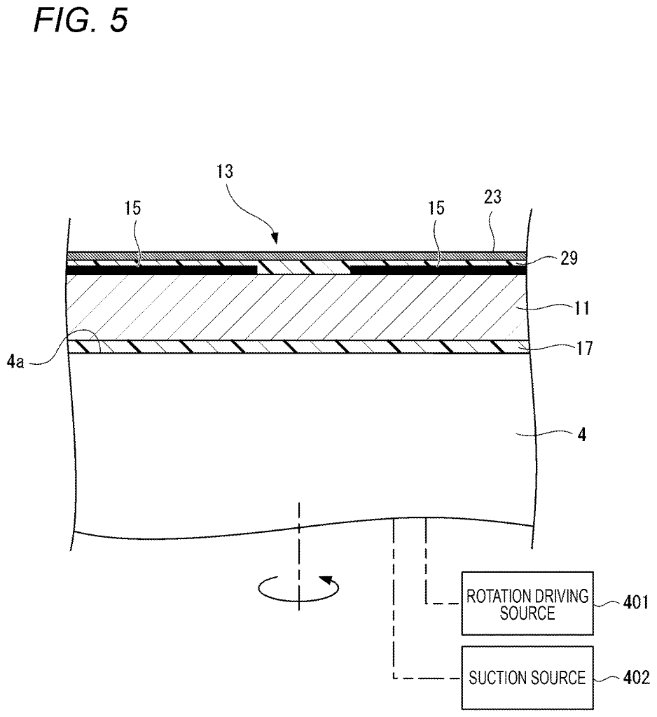

As shown in FIGS. 4 and 5, in the protective film forming step S11, the surface of the base film 29 formed on the workpiece 11 is coated with the protective film agent to form a protective film 23. FIG. 4 is a cross-sectional view showing how the workpiece 11 is coated with the protective film agent. FIG. 5 is a cross-sectional view showing a state in which the protective film 23 is formed on the workpiece 11. In FIGS. 4 and 5, for convenience of description, side surfaces of only some elements are shown.

In the protective film forming step S11, as in the base film forming step S10, the surface of the base film 29 is coated with the protective film agent using the spin coater 2. In the protective film forming step S11, the protective film agent is dropped from the nozzle 6, and the spinner table 4 is rotated to apply the protective film agent to the base film 29 formed on the workpiece 11. Although conditions for coating the protective film agent are not particularly limited, typically, when a diameter of the workpiece 11 is 200 mm, an amount of the protective film agent to be dropped is 20 ml to 50 ml, a rotation speed (rotation speed) of the spinner table 4 is 200 rpm to 3000 rpm, and a time for rotating the spinner table 4 is 30 seconds to 360 seconds.

In the mask forming step S12, a laser beam having a wavelength absorbed by the base film 29 and the protective film 23 is emitted along the planned processing lines 13 set on the front surface 11a of the workpiece 11 to remove portions of the base film 29 and the protective film 23 overlapping the planned processing lines 13, thereby forming a mask 27.

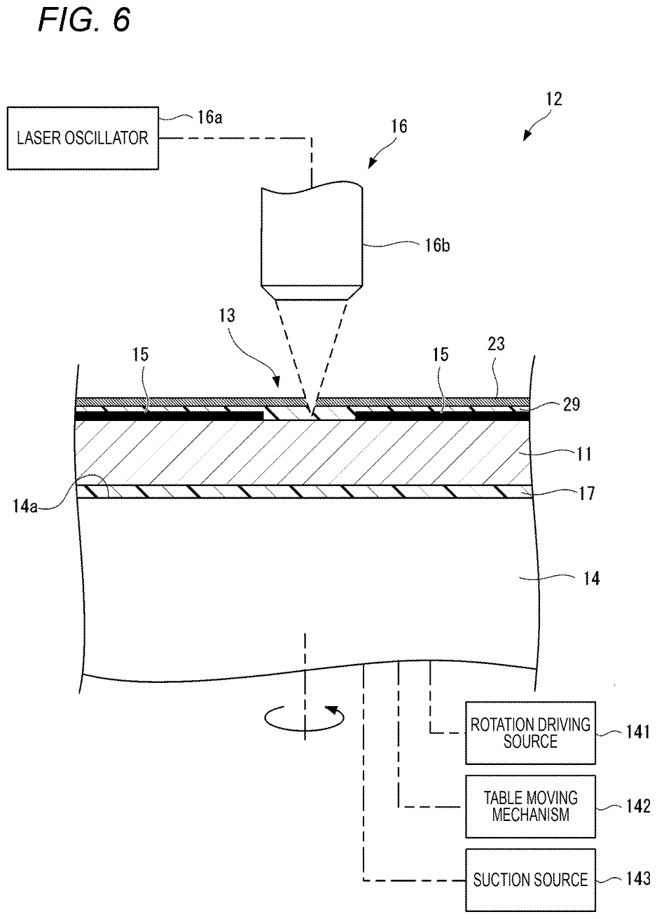

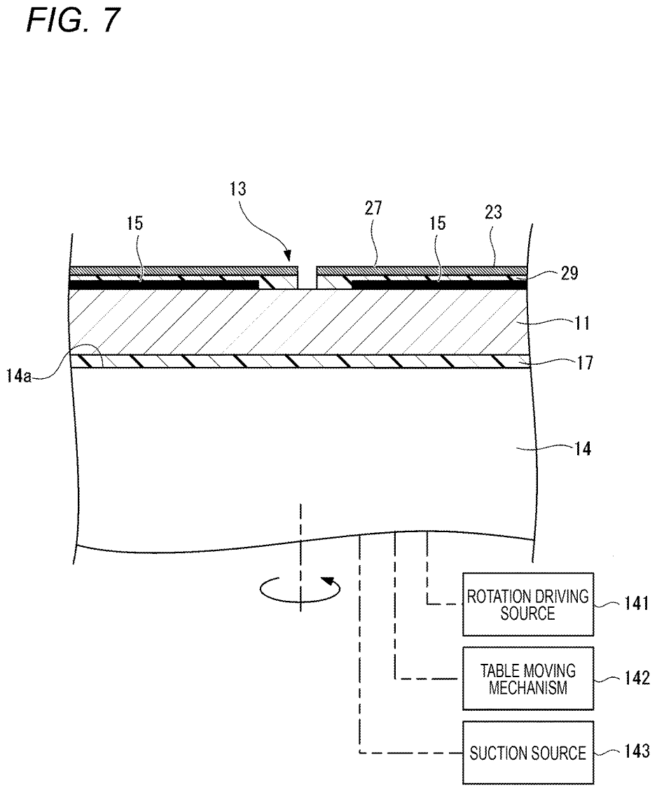

FIG. 6 is a cross-sectional view showing a state in which the base film 29 and the protective film 23 are irradiated with a laser beam. FIG. 7 is a cross-sectional view showing a state in which the mask 27 is formed on the workpiece 11. In FIGS. 6 and 7, for convenience of description, side surfaces of only some elements are also shown.

A laser processing apparatus 12 is used to irradiate the base film 29 and the protective film 23 with a laser beam. The laser processing apparatus 12 includes a chuck table (holding table) 14 for holding the workpiece 11 and a laser irradiation unit 16 for emitting a laser beam.

The chuck table 14 is coupled to a rotation driving source 141 including a motor and the like, and rotates around a rotation axis substantially parallel to a vertical direction. Further, the chuck table 14 is provided with a table moving mechanism 142 including a ball screw, a motor, and the like, and the chuck table 14 is movable in a processing feed direction and an indexing feed direction orthogonal to the processing feed direction by the table moving mechanism 142.

A part of an upper surface of the chuck table 14 serves as a holding surface 14a for holding the workpiece 11. The holding surface 14a is connected to a suction source 143 such as a vacuum pump via a flow path formed inside the chuck table 14. A plurality of clamps (not shown) for fixing the frame 19 are provided around the chuck table 14.

A processing head 16b of the laser irradiation unit 16 is disposed above the chuck table 14. The laser irradiation unit 16 focuses a pulsed laser beam generated by laser oscillation of a laser oscillator 16a at a predetermined position by the processing head 16b.

The laser oscillator 16a oscillates a laser beam having a wavelength absorbed by the base film 29 and the protective film 23. A wavelength of the laser beam oscillated by the laser oscillator 16a is, for example, a wavelength in an ultraviolet region (preferably 250 nm to 400 nm), but the wavelength is not particularly limited.

To describe the mask forming step S12 in detail, first, in the mask forming step S12, the tape 17 attached to the back surface 11b of the workpiece 11 is brought into contact with the holding surface 14a of the chuck table 14 to apply a negative pressure of the suction source 143, and the frame 19 is fixed by clamps. Thus, the workpiece 11 is held on the chuck table 14 with the protective film 23 exposed upward.

Subsequently, in the mask forming step S12, the chuck table 14 is rotated to align an extending direction of the target planned processing line 13 with the processing feed direction of the laser processing apparatus 12. In the mask forming step S12, the chuck table 14 is moved to align a position of the processing head 16b of the laser irradiation unit 16 above an extension line of the target planned processing line 13, for example.

Subsequently, in the mask forming step S12, the chuck table 14 is moved in the processing feed direction while the laser beam is emitted from the processing head 16b toward the front surface 11a of the workpiece 11, and the processing head 16b and the workpiece 11 are relatively moved. The laser irradiation unit 16 focuses a laser beam on, for example, a surface or the inside of the protective film 23.

The power of the laser beam is set to, for example, 0.1 W to 100 W, typically 0.5 W. A spot diameter on a target surface is adjusted to, for example, about 1 μm to 100 μm, and typically about 5 μm to 15 μm. A repetition frequency is set to, for example, 100 kHz to 50000 kHz, typically 100 kHz to 1000 kHz. A pulse width is set to, for example, 10 femtoseconds to 500 nanoseconds, typically 3 picoseconds to 30 picoseconds. A moving speed of the chuck table 14 is set to 20 mm/s to 5000 mm/s, typically 20 mm/s to 1000 mm/s. However, conditions for emitting the laser beam are not particularly limited. Further, in the embodiment, the laser beam is emitted under a condition that the workpiece 11 is hardly processed, or the workpiece 11 may be partially processed by this laser beam.

Thus, the laser beam is emitted along the planned processing lines 13 to remove the portions of the base film 29 and the protective film 23 overlapping the planned processing lines 13. By repeating such an operation to remove the portions of the base film 29 and the protective film 23 overlapping all the planned processing lines 13, the mask 27 covering a region corresponding to the device 15 of the workpiece 11 is formed.

In the plasma etching step S13, after the mask forming step S12, a portion of the workpiece 11 exposed from the mask 27 is processed by applying plasma to the workpiece 11 through the mask 27.

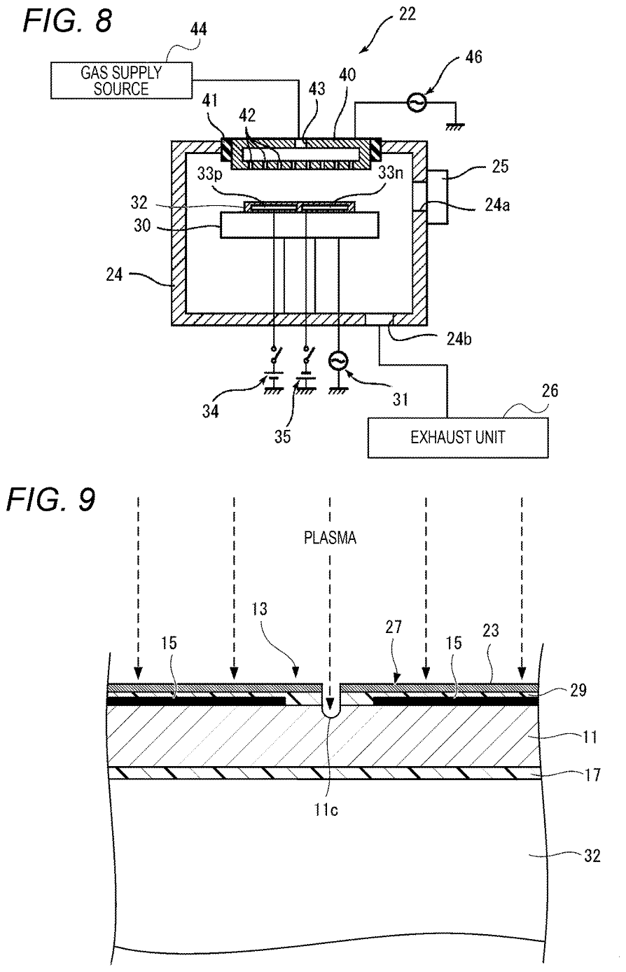

FIG. 8 is a cross-sectional view showing a plasma etching apparatus 22. FIG. 9 is a cross-sectional view showing how the workpiece 11 is processed by plasma. In FIG. 8, for convenience of description, some elements of the plasma etching apparatus 22 are represented by symbols or functional blocks. In FIG. 9, side surfaces of some elements are shown.

When the workpiece 11 is processed by plasma, for example, the plasma etching apparatus 22 is used. The plasma etching apparatus 22 includes a vacuum chamber 24 therein. An opening 24a having a size through which the workpiece 11 and the frame 19 pass is formed in a side wall of the vacuum chamber 24. A cover 25 having a size capable of covering the opening 24a is provided outside the opening 24a.

An opening and closing mechanism (not shown) is coupled to the cover 25, and the cover 25 is opened and closed by the opening and closing mechanism. By opening the cover 25 to expose the opening 24a, the workpiece 11 can be carried into a space inside the vacuum chamber 24 through the opening 24a, or the workpiece 11 can be carried out from the space inside the vacuum chamber 24.

An exhaust port 24b is formed in a bottom wall of the vacuum chamber 24. The exhaust port 24b is connected to an exhaust unit 26 such as a vacuum pump.

A lower electrode 30 is disposed in the vacuum chamber 24. The lower electrode 30 is formed in a disk shape using a conductive material, and is connected to a radio frequency power supply 31 provided outside the vacuum chamber 24.

An electrostatic chuck 32 is disposed on an upper surface of the lower electrode 30. The electrostatic chuck 32 includes, for example, an electrode 33p and an electrode 33n that are insulated from each other, and holds the workpiece 11 by an electrical force acting between the electrode 33p and the electrode 33n and the workpiece 11. For example, a positive electrode of a DC power supply 34 can be connected to the electrode 33p, and a negative electrode of a DC power supply 35 can be connected to the electrode 33n. The DC power supply 34 and the DC power supply 35 may be the same single DC power supply.

An upper electrode 40 formed in a disk shape using a conductive material is attached to a ceiling wall of the vacuum chamber 24 via an insulating member 41. A plurality of gas ejection holes 42 are formed on a lower surface side of the upper electrode 40, and the gas ejection holes 42 are connected to a gas supply source 44 via gas supply holes 43 provided on an upper surface side of the upper electrode 40. Accordingly, a gas for plasma etching can be supplied from the gas supply source 44 to the vacuum chamber 24. The upper electrode 40 is connected to a radio frequency power supply 46 provided outside the vacuum chamber 24.

In the plasma etching step S13, first, the cover 25 is opened by the opening and closing mechanism, and the workpiece 11 is carried into the vacuum chamber 24 through the opening 24a and placed on the electrostatic chuck 32. Specifically, as shown in FIG. 9, the tape 17 attached to the back surface 11b side of the workpiece 11 is brought into contact with an upper surface of the electrostatic chuck 32. Thereafter, when the electrostatic chuck 32 is operated, the workpiece 11 is held in a state where the mask 27 provided on the front surface 11a side is exposed upward.

Subsequently, in the plasma etching step S13, plasma (indicated by dashed arrows in FIG. 9) is applied to the workpiece 11 through the mask 27 to process the workpiece 11 along the planned processing line 13. Specifically, the cover 25 is closed by the opening and closing mechanism to seal the vacuum chamber 24. Further, the exhaust unit 26 is operated to depressurize the vacuum chamber 24. In this state, when appropriate radio frequency power is supplied to the lower electrode 30 and the upper electrode 40 by the radio frequency power supply 31 and the radio frequency power supply 46 while supplying a gas for plasma etching from the gas supply source 44 at a predetermined flow rate, plasma containing radicals, ions, or the like is generated between the lower electrode 30 and the upper electrode 40.

Thus, a portion not covered with the mask 27 can be exposed to plasma to process the workpiece 11. The gas for plasma etching supplied from the gas supply source 44 is appropriately selected according to the material of the workpiece 11 and the like.

When the workpiece 11 is desired to be deeply processed along a thickness direction as in the case of dividing the workpiece 11 along the planned processing lines 13, three steps of groove formation, film formation, and partial film removal are preferably repeated. Here, the steps of groove formation, film formation, and partial film removal step in the plasma etching step S13 will be described by taking a case where the workpiece 11 is a wafer formed using silicon as an example.

In the groove formation step, for example, while the pressure inside the vacuum chamber 24 is kept constant, SF6 is supplied from the gas supply source 44 at a predetermined flow rate, and predetermined radio frequency power is supplied to the lower electrode 30 and the upper electrode 40. Accordingly, for example, plasma such as radicals or ions using SF6 as a raw material is generated, and a portion of the workpiece 11 not covered with the mask 27 can be processed. As a result, as shown in FIG. 9, a shallow processed groove 11c is formed in the planned processing line 13 of the workpiece 11.

In the film formation step, for example, C4F8 is supplied from the gas supply source 44 at a predetermined flow rate while maintaining the pressure inside the vacuum chamber 24 constant, and predetermined radio frequency power is supplied to the lower electrode 30 and the upper electrode 40. As a result, a fluorine-based material is deposited inside the processed groove 11c to form a thin film (not shown) covering an inner surface of the processed groove 11c. The film made of the fluorine-based material has a predetermined resistance to plasma generated using SF6 as a raw material.

In the partial film removal step, for example, while the pressure inside the vacuum chamber 24 is kept constant, SF6 is supplied from the gas supply source 44 at a predetermined flow rate, and predetermined radio frequency power is supplied to the lower electrode 30 and the upper electrode 40. In the partial film removal step, the power supplied to the lower electrode 30 is made larger than that in the groove formation step.

When the power supplied to the lower electrode 30 is increased, the anisotropy of etching by plasma is increased. Specifically, a film formed on a bottom surface side of the processed groove 11c is preferentially processed. That is, the film formed on the bottom surface side of the processed groove 11c is removed by the plasma generated using SF6 as a raw material, and a film formed on a side surface of the processed groove 11c is maintained.

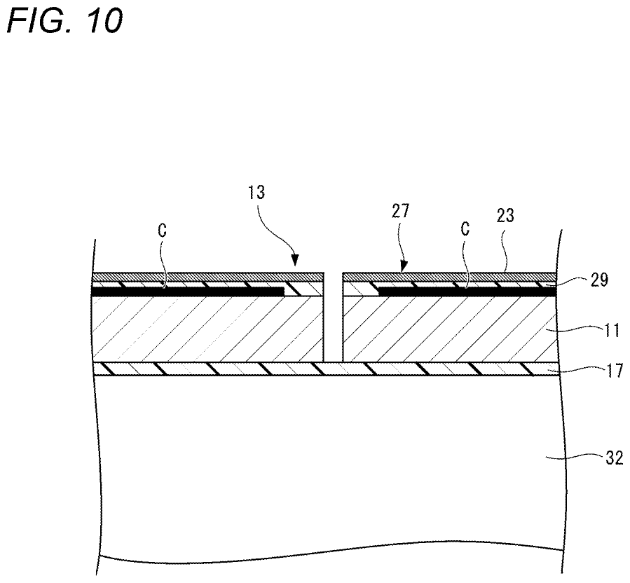

By repeating the three steps of groove formation, film formation, and partial film removal, the processed groove 11c can be gradually deepened, and finally, the workpiece 11 can be divided along the planned processing lines 13. FIG. 10 is a cross-sectional view schematically showing the workpiece 11 divided along the planned processing lines 13. In FIG. 10, for convenience of description, side surfaces of some elements are also shown. As shown in FIG. 10, when the workpiece 11 is divided along the planned processing lines 13, a plurality of device chips C are formed.

In the cleaning step S14, after the plasma etching step S13, the base film 29 and the protective film 23 are removed from the workpiece 11 (device chips C) by ejecting a fluid.

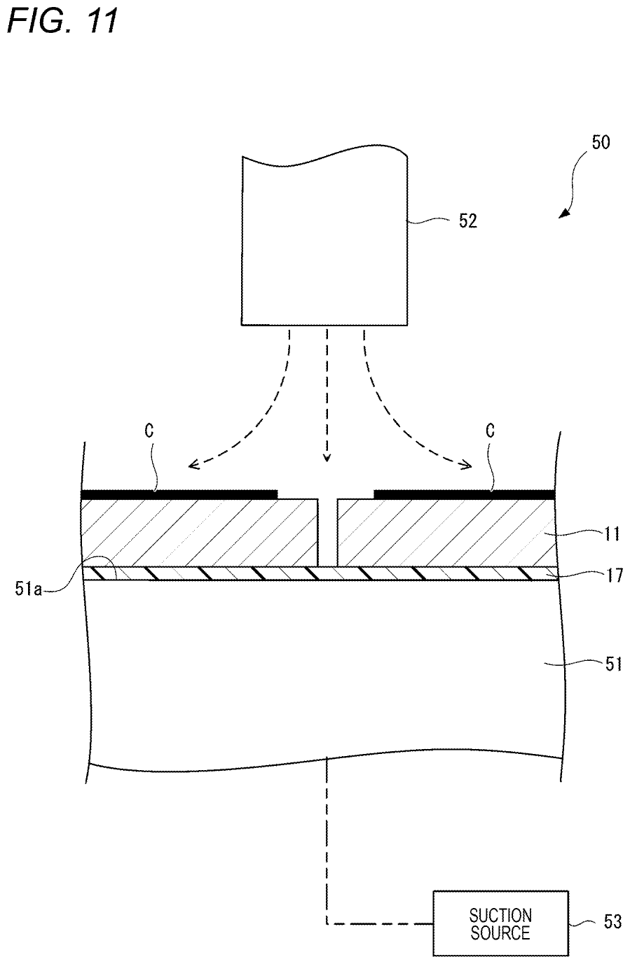

FIG. 11 is a cross-sectional view showing a state in which the base film 29 and the protective film 23 are removed by a cleaning device 50. The cleaning device 50 is used to remove the base film 29 and the protective film 23 from the workpiece 11. The cleaning device 50 includes a holding table 51 for holding the workpiece 11 and a nozzle 52 for ejecting a fluid.

A part of an upper surface of the holding table 51 serves as a holding surface 51a for holding the workpiece 11. The holding surface 51a is connected to a suction source 53 such as a vacuum pump via a flow path formed inside the holding table 51. A plurality of clamps (not shown) for fixing the annular frame 19 are provided around the holding table 51.

The nozzle 52 is disposed above the holding table 51 and ejects a fluid to the workpiece 11. Specifically, the nozzle 52 is disposed on a central axis of the workpiece 11. The fluid ejected from the nozzle 52 is, for example, a gas-liquid mixed fluid in which a liquid (for example, water) and a gas (for example, air) are mixed. That is, in the cleaning step S14, the base film 29 and the protective film 23 are removed by two-fluid cleaning. The fluid ejected from the nozzle 52 is not limited to the gas-liquid mixed fluid, and may be only liquid or only gas.

Hereinafter, experiments and results thereof performed to confirm the cleaning effect in the case of using the above-described base film agent will be described. First, a base film agent shown in Experimental Examples 1 to 3 below was prepared. In addition, as Comparative Example 1, a base film agent containing a water-soluble compound (polyvinyl alcohol) having a large molecular weight was prepared. In addition, as Comparative Example 2, an experiment in which the base film agent was not used was also performed.

In Experimental Example 1, 5 parts by mass of trimethylolpropane (TMP) as a water-soluble compound was gradually added to 95 parts by mass of a solvent (water: 79 parts by mass, propylene glycol monomethyl ether (PGME): 16 parts by mass), and the mixture was stirred until dissolution. Thus, a base film agent in Experimental Example 1 was obtained.

In Experimental Example 2, 50 parts by mass of TMP as a water-soluble compound was gradually added to 50 parts by mass of a solvent (water: 15 parts by mass, dipropylene glycol monomethyl ether (DPM): 35 parts by mass), and the mixture was stirred until dissolution. Thus, a base film agent in Experimental Example 2 was obtained.

In Experimental Example 3, 1 part by mass of TMP as a water-soluble compound was gradually added to 99 parts by mass of a solvent (water: 89 parts by mass, PGME: 10 parts by mass), and the mixture was stirred until dissolution. Thus, a base film agent in Experimental Example 3 was obtained.

In Comparative Example 1, 5 parts by mass of polyvinyl alcohol (number average molecular weight: about 15,000) as a water-soluble compound was gradually added to 95 parts by mass of a solvent (water: 79 parts by mass, propylene glycol monomethyl ether (PGME): 16 parts by mass), and the mixture was stirred until dissolution. Thus, a base film agent in Comparative Example 1 was obtained.

In Comparative Example 2, the base film agent was not prepared.

In Experimental Examples 1 to 3, 50 wt % or more of the water-soluble compounds of the base film agent is trimethylolpropane (molecular weight: 2000 or less), and in Comparative Example 1, 50 wt % or more of the water-soluble compounds of the base film agent is polyvinyl alcohol (molecular weight: 2000 or more).

A protective film agent used in each of Experimental Examples 1 to 3 and Comparative Examples 1, 2 was obtained as follows. 15 parts by mass of polyvinyl alcohol as a water-soluble resin was gradually added to 75 parts by mass of a solvent (water: 62 parts by mass, propylene glycol monomethyl ether (PGME): 13 parts by mass), and the mixture was stirred until dissolution. Thereafter, 5 parts by mass of trimethylolpropane (TMP) as a plasticizer and 5 parts by mass of α-glycosyl rutin as a light absorbing material were gradually added to the solution, and the mixture was stirred until dissolution. Thus, a protective film agent was obtained.

In each of Experimental Examples 1 to 3 and Comparative Example 1, a base film was formed on a wafer by spin coating using the prepared base film agent, and a protective film was formed on a surface of the base film by spin coating using the prepared protective film agent. In Comparative Example 2, the protective film was formed on a surface of the wafer by spin coating using the prepared protective film agent without forming the base film. In each of Experimental Examples 1 to 3 and Comparative Examples 1, 2, a fluid was ejected to a wafer. The effect of removing the base film and the protective film by the fluid cleaning was evaluated by the number of particles having a size of 0.15 μm or more which remained on the surface of the wafer.

As a result of the evaluation, it was confirmed that in Comparative Examples 1 and 2, the number of remained particles was 10,000 or more, whereas in Experimental Examples 1 to 3, the number of remained particles was less than 10,000, and in Experimental Examples 1 to 3, the number of particles remained on the surface of the wafer was smaller than that in Comparative Examples 1 and 2.

As described above, it can be seen that, when the base film is formed on the wafer using the base film agent in which 50 wt % or more of the water-soluble compounds has a molecular weight of 2000 or less, a large amount of particles on the surface of the wafer can be removed by the fluid cleaning and the cleaning performance is high, as compared with a case where the base film is not formed on the wafer as in Comparative Example 2. In addition, it can be seen that, as compared with a case where the base film is formed on the wafer using the base film agent in which 50 wt % or more of the water-soluble compounds has a molecular weight of 2000 or more as in Comparative Example 1, a large amount of particles on the surface of the wafer can be removed by the fluid cleaning, and the cleaning performance is high.

### Second Embodiment

In the first embodiment, the mask 27 for plasma etching is formed using the protective film agent, or the protective film agent can also be used in the processing method for the workpiece 11 using laser ablation.

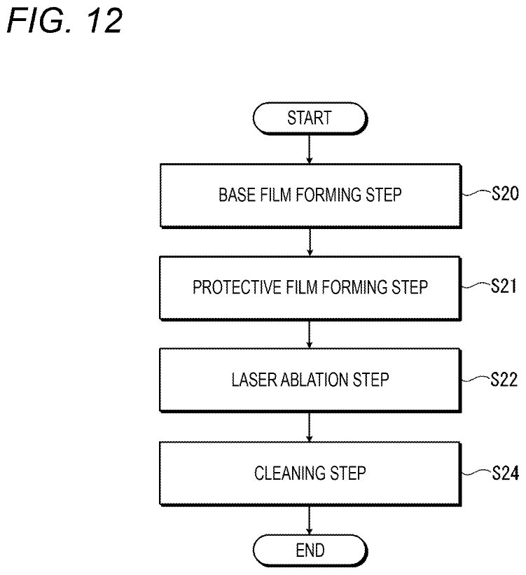

FIG. 12 is a flowchart showing a processing method for the workpiece 11 according to the second embodiment. The processing method for the workpiece 11 according to the second embodiment includes a base film forming step S20, a protective film forming step S21, a laser ablation step S22, and a cleaning step S24. Since the base film forming step S20, the protective film forming step S21, and the cleaning step S24 are the same as the base film forming step S10, the protective film forming step S11, and the cleaning step S14 according to the first embodiment, description thereof will be omitted.

In the laser ablation step S22, portions of the base film 29 and the protective film 23 overlapping the planned processing lines 13 and portions of the workpiece 11 overlapping the planned processing line 13 are removed by applying a laser beam having a wavelength absorbed by both the base film 29, the protective film 23, and the workpiece 11 along the planned processing lines 13 set on the workpiece 11.

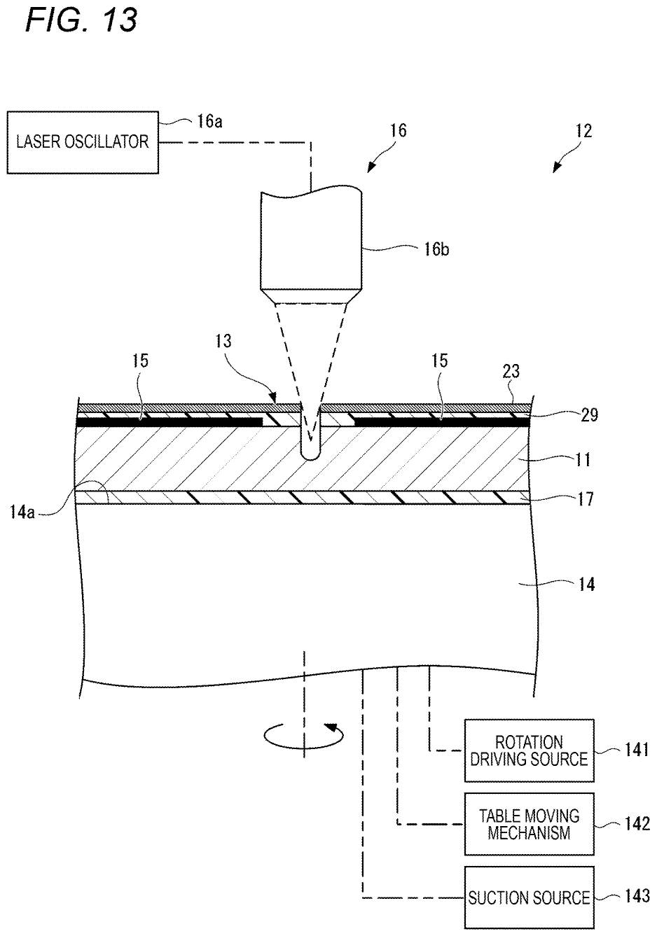

FIG. 13 is a cross-sectional view showing how the workpiece 11 is processed by a laser beam. In FIG. 13, for convenience of description, side surfaces of some elements are also shown. The above-described laser processing apparatus 12 can also be used when the base film 29, the protective film 23, and the workpiece 11 are irradiated with a laser beam.

In the second embodiment, the laser oscillator 16a generates a laser beam having a wavelength in the ultraviolet region absorbed by the base film 29, the protective film 23, and the workpiece 11. That is, the wavelength of the laser beam generated by the laser oscillator 16a is a wavelength in the ultraviolet region (preferably 250 nm to 400 nm), and is typically 355 nm. A procedure for processing the base film 29, the protective film 23, and the workpiece 11 by applying a laser beam is the same as a procedure for forming the mask 27 by applying a laser beam to the base film 29 and the protective film 23. In the second embodiment, a laser beam may be focused on the front surface 11a of the workpiece 11 or inside the workpiece 11.

The power of the laser beam is set to, for example, 0.1 W to 100 W, typically 0.5 W to 15 W, a spot diameter on a surface of a target is adjusted to, for example, 1 μm to 100 μm, typically 30 μm to 60 μm, a pulse width is set to, for example, 10 femtoseconds to 500 nanoseconds, a repetition frequency is set to, for example, 20 kHz to 50000 kHz, typically 20 kHz to 2000 kHz, and the moving speed of the chuck table 14 is set to 20 mm/s to 5000 mm/s, typically 100 mm/s to 1000 mm/s. In the second embodiment, it is necessary to emit a laser beam under a condition that the base film 29, the protective film 23, and the workpiece 11 are processed. As a result, the portions of the base film 29 and the protective film 23 overlapping the planned processing lines 13 and the portions of the workpiece 11 overlapping the planned processing lines 13 can be removed.

Although the embodiments of the present disclosure have been described above with reference to the accompanying drawings, it is needless to say that the present disclosure is not limited to the embodiments. It is obvious that those skilled in the art may come up with various changes or modifications within the scope of the claims, and it is understood that these naturally fall within the technical scope of the present disclosure. In addition, components in the embodiment described above may be freely combined without departing from the gist of the disclosure.

The present specification describes at least the following matters. Corresponding components and the like in the embodiments described above are shown in parentheses as an example, but the present disclosure is not limited thereto.
(1) A base film agent for a protective film (protective film 23) coated on a workpiece (workpiece 11) when the workpiece is processed, the base film agent including:
water-soluble compounds; and
a solvent that dissolves the water-soluble compounds, in which
50 wt % or more of the water-soluble compounds has a molecular weight of 2000 or less.

According to (1), by coating the workpiece with the base film agent in which 50 wt % or more of the water-soluble compounds has a molecular weight of 2000 or less as the base film of the protective film, the protective film can be prevented from remaining on the workpiece when the protective film is cleaned.
(2) The base film agent for a protective film according to (1), in which
a component having a molecular weight of 2000 or less in the water-soluble compounds is a compound containing one or more hydroxyl groups.

According to (2), the cleaning performance for removing the protective film from the workpiece can be enhanced.
(3) The base film agent for a protective film according to (1), in which
a component having a molecular weight of 2000 or less in the water-soluble compounds is solid at 20° C.

According to (3), the cleaning performance for removing the protective film from the workpiece can be enhanced.
(4) The base film agent for a protective film according to (1), in which
50 wt % or more of the water-soluble compounds is trimethylolpropane.

According to (4), the cleaning performance for removing the protective film from the workpiece can be enhanced by using the base film agent containing trimethylolpropane.
(5) A processing method for a workpiece, the processing method including:
forming a base film (base film 29) by coating a surface of the workpiece with the base film agent according to any one of (1) to (4);
forming the protective film by coating a surface of the base film with a protective film agent;
removing portions of the protective film and the base film overlapping planned processing lines (planned processing line 13) set on the workpiece by irradiating the workpiece with a laser beam having a wavelength absorbed by the protective film and the base film along the planned processing lines, thereby forming a mask (mask 27);
removing portions of the workpiece exposed from the mask by applying plasma to the portions exposed from the mask; and
removing the protective film and the base film from the workpiece by applying plasma to the workpiece and then ejecting a fluid.

According to (5), by coating the workpiece with the base film agent according to any one of (1) to (4), the protective film that functions as a mask when the plasma is applied can be prevented from remaining on the workpiece.
(6) A processing method for a workpiece, the processing method including:
forming a base film by coating a surface of the workpiece with the base film agent according to any one of (1) to (4);
forming the protective film by coating a surface of the base film with a protective film agent;
removing portions of the protective film, the base film, and the workpiece overlapping planned processing lines set on the workpiece by irradiating the workpiece with a laser beam having a wavelength absorbed by the protective film, the base film, and the workpiece along the planned processing lines; and
removing the protective film and the base film from the workpiece by ejecting a fluid after irradiating the workpiece with the laser beam.

According to (6), by coating the workpiece with the base film agent according to any one of (1) to (4), the protective film can be prevented from remaining on the workpiece during laser ablation.

### REFERENCE SIGNS LIST

11 workpiece
13 planned processing line
23 protective film
27 mask
29 base film

What is claimed is:

1. A base film agent comprising:
water-soluble compounds; and
a solvent that dissolves the water-soluble compounds, wherein
50 wt % or more of the water-soluble compounds has a molecular weight of 2000 or less.

2. The base film agent according to claim 1, wherein
a component having a molecular weight of 2000 or less in the water-soluble compounds is a compound containing one or more hydroxyl groups.

3. The base film agent according to claim 1, wherein
a component having a molecular weight of 2000 or less in the water-soluble compounds is solid at 20° C.

4. The base film agent according to claim 1, wherein
50 wt % or more of the water-soluble compounds is trimethylolpropane.

5. A processing method for a workpiece, the processing method comprising:
forming a base film by coating a surface of the workpiece with the base film agent according to claim 1;
forming a protective film by coating a surface of the base film with a protective film agent;
removing portions of the protective film and the base film overlapping planned processing lines set on the workpiece by irradiating the workpiece with a laser beam having a wavelength absorbed by the protective film and the base film along the planned processing lines, thereby forming a mask;
removing portions of the workpiece exposed from the mask by applying plasma to the portions exposed from the mask; and
removing the protective film and the base film from the workpiece by applying plasma to the workpiece and then ejecting a fluid to the workpiece.

6. A processing method for a workpiece, the processing method comprising:
forming a base film by coating a surface of the workpiece with the base film agent according to claim 1;
forming a protective film by coating a surface of the base film with a protective film agent;
removing portions of the protective film, the base film, and the workpiece overlapping planned processing lines set on the workpiece by irradiating the workpiece with a laser beam having a wavelength absorbed by the protective film, the base film, and the workpiece along the planned processing lines; and
removing the protective film and the base film from the workpiece by ejecting a fluid to the workpiece after irradiating the workpiece with the laser beam.

7. A device chip manufacturing method in which a workpiece is divided along a plurality of planned processing lines to form a plurality of device chips, the method comprising:
forming a base film by coating a surface of the workpiece with the base film agent according to claim 1;
forming a protective film by coating a surface of the base film with a protective film agent;
removing portions of the protective film and the base film overlapping the planned processing lines set on the workpiece by irradiating the workpiece with a laser beam having a wavelength absorbed by the protective film and the base film along the planned processing lines, thereby forming a mask;
removing portions of the workpiece exposed from the mask by applying plasma to the portions exposed from the mask, thereby dividing the workpiece along the planned processing lines; and
removing the protective film and the base film from the workpiece by applying plasma to the workpiece and then ejecting a fluid to the workpiece.

8. A device chip manufacturing method in which a workpiece is divided along a plurality of planned processing lines to form a plurality of device chips, the method comprising:
forming a base film by coating a surface of the workpiece with the base film agent according to claim 1;
forming a protective film by coating a surface of the base film with a protective film agent;
removing portions of the protective film, the base film, and the workpiece overlapping the planned processing lines set on the workpiece by irradiating the workpiece with a laser beam having a wavelength absorbed by the protective film, the base film, and the workpiece along the planned processing lines, thereby dividing the workpiece along the planned processing lines; and
removing the protective film and the base film from the workpiece by ejecting a fluid to the workpiece after irradiating the workpiece with the laser beam.
